(19) United States
(12) Patent Application Publication
(10) Pub. No.: US 2025/0008724 A1
(43) Pub. Date: Jan. 2, 2025

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Jun Ha KWAK, Gyeonggi-do (KR)

(21) Appl. No.: 18/537,893

(22) Filed: Dec. 13, 2023

(30) Foreign Application Priority Data
Jun. 30, 2023 (KR) 10-2023-0085304

(51) Int. Cl. H10B 12/00

(52) U.S. Cl. CPC H10B 12/30; H10B 12/03; H10B 12/05

(57) ABSTRACT

A semiconductor device includes: a lower structure; a plurality of horizontal layers horizontally oriented over the lower structure; a first conductive line commonly coupled to first ends of the horizontal layers and extending in a direction perpendicular to the lower structure; a plurality of second conductive lines crossing the horizontal layers, respectively; a plurality of data storage elements coupled to second ends of the horizontal layers, respectively, and stacked in a direction perpendicular to the lower structure; capping layers disposed between the second conductive lines and the first conductive line; and blocking layers disposed between the capping layers and the first conductive line.

### CROSS-REFERENCE TO RELATED APPLICATIONS

The present application claims priority under 35 U.S.C 119(a) to Korean Patent Application No. 10-2023-0085304, filed on Jun. 30, 2023, in the Korean Intellectual Property Office, which is incorporated herein by reference in its entirety.

### BACKGROUND

### 1. Field

Various embodiments of the present invention relate to a semiconductor device, and more particularly, to a semiconductor device including three-dimensional memory cells, and a method for fabricating the semiconductor device.

### 2. Description of the Related Art

Recently, to cope with the increase in capacity and miniaturization of memory devices, a technology for providing a three-dimensional (3D) memory device in which a plurality of memory cells are stacked is being suggested.

### SUMMARY

Embodiments of the present invention are directed to a semiconductor device including highly integrated memory cells, and a method for fabricating the semiconductor device.

In accordance with an embodiment of the present invention, a semiconductor device includes: a lower structure; a plurality of horizontal layers horizontally oriented over the lower structure; a first conductive line commonly coupled to first ends of the horizontal layers and extending in a direction perpendicular to the lower structure; a plurality of second conductive lines crossing the horizontal layers, respectively; a plurality of data storage elements coupled to second ends of the horizontal layers, respectively, and stacked in the direction perpendicular to the lower structure; a plurality of capping layers disposed between the second conductive lines and the first conductive line; and a plurality of the blocking layers disposed between the capping layers and the first conductive line.

In accordance with another embodiment of the present invention, a method for fabricating a semiconductor device includes: forming a horizontal layer over a lower structure; forming a horizontal conductive line crossing the horizontal layer; forming a capping layer on a side surface of the horizontal conductive line; forming a blocking layer over the capping layer; forming a vertically oriented vertical conductive line over the blocking layer to be coupled to a first end of the horizontal layer; and forming a data storage element coupled to a second end of the horizontal layer. The forming of the blocking layer includes selectively growing the blocking layer from a surface of the capping layer. In the selectively forming the blocking layer from the surface of the capping layer, the blocking layer is formed by an area selective deposition (ASD) method. The capping layer includes silicon nitride, and the blocking layer includes silicon carbon oxide. The capping layer includes a stack of silicon oxide and silicon nitride, and the blocking layer includes silicon carbon oxide selectively deposited from a surface of the silicon nitride.

In accordance with diverse embodiments of the present invention, a bridge between horizontal conductive lines and vertical conductive lines may be prevented by forming blocking layers.

### BRIEF DESCRIPTION OF THE DRAWINGS

FIG. 1A is a schematic perspective view illustrating a memory cell in accordance with an embodiment of the present invention.

FIG. 1B is a schematic cross-sectional view illustrating the memory cell shown in FIG. 1A.

FIG. 1C is a plan view illustrating a switching element shown in FIG. 1A.

FIG. 2 is a schematic plan view illustrating a semiconductor device in accordance with an embodiment of the present invention.

FIG. 3A is a schematic perspective view illustrating a first memory cell array MCA1 shown in FIG. 2.

FIG. 3B is a schematic cross-sectional view illustrating the first memory cell array MCA1 shown in FIG. 2.

FIGS. 4 to 24 illustrate a method for fabricating a semiconductor device in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The embodiments described below relate to three-dimensional memory cells vertically stacked for increasing the memory cell density and for reducing parasitic capacitance.

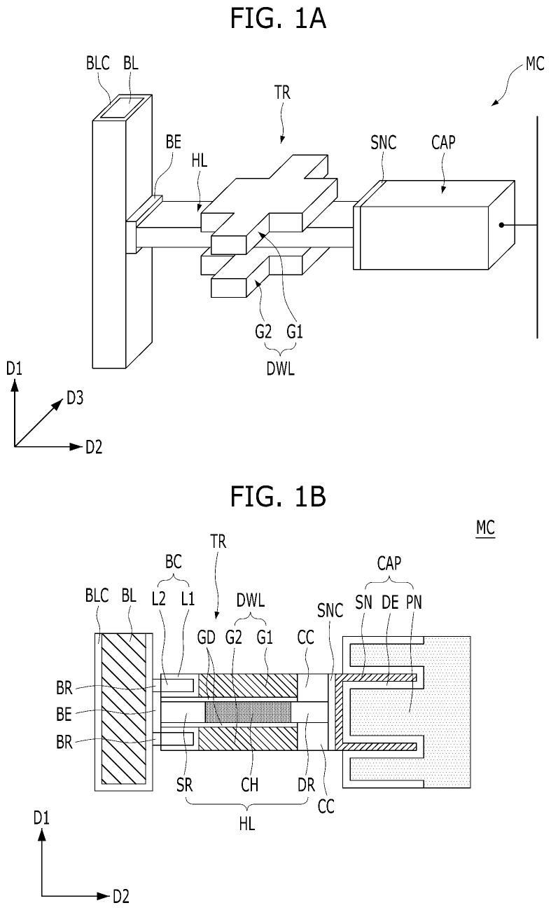

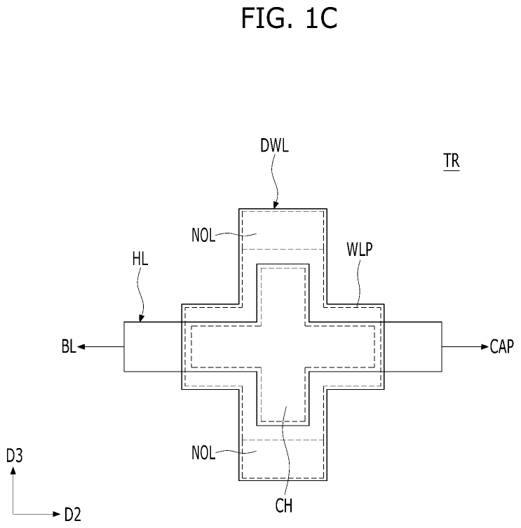

FIG. 1A is a schematic perspective view illustrating a memory cell in accordance with an embodiment of the present invention. FIG. 1B is a schematic cross-sectional view illustrating the memory cell shown in FIG. 1A. FIG. 1C is a plan view illustrating a switching element shown in FIG. 1A.

Referring to FIGS. 1A to 1C, a memory cell MC may include a first conductive line BL, a switching element TR, and a data storage element CAP. The switching element TR may include a horizontal layer HL, a inter-level dielectric layer GD, and a horizontal conductive layer DWL. The data storage element CAP may include a memory element, such as, for example, a capacitor. The first conductive line BL may include, for example, a bit line. The second conductive line DWL may include, for example, a word line, and the horizontal layer HL may include, for example, an active layer. The data storage element CAP may include a first electrode SN, a dielectric layer DE, and a second electrode PN. The switching element TR may include, for example, a transistor, and the second conductive line DWL may serve as a gate electrode for the transistor. The switching element TR may also be referred to as a transistor, a cell transistor, an access element, or a selection element.

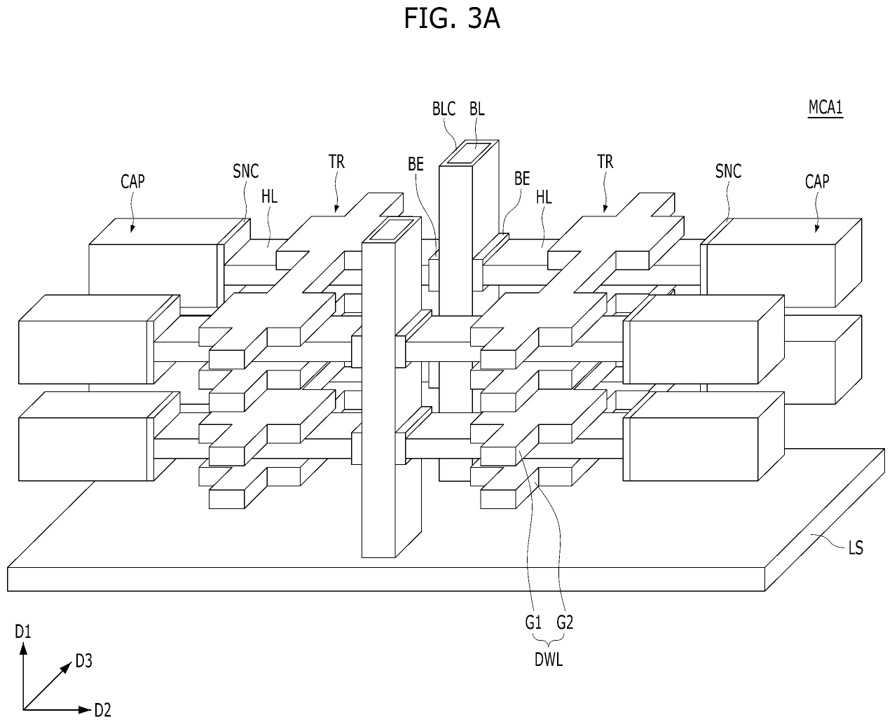

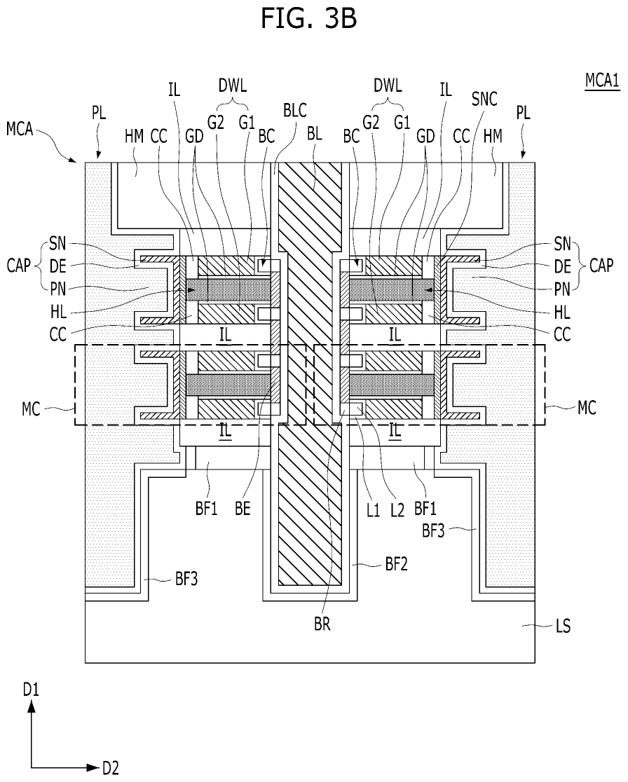

The first conductive line BL may extend vertically in a first direction D1. The horizontal layer HL may extend in a second direction D2 crossing the first direction D1. The second conductive line DWL may extend in a third direction D3 crossing the first and second directions D1 and D2. The second and third directions may extend parallel to a lower structure LS (see FIG. 3A). The second direction D2 may be referred to as a first horizontal direction, and the third direction D3 may be referred to as a second horizontal direction.

The first conductive line BL may be vertically oriented in the first direction D1. The first conductive line BL may also be referred to as a vertically-oriented bit line, a vertically-extended bit line, a vertical conductive line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include polysilicon or titanium nitride (TiN) that is doped with an N-type impurity. The first conductive line BL may include a stack (TiN/W) of titanium nitride and tungsten.

The switching element TR may include a transistor, and thus, the second conductive line DWL may be referred to as a horizontal gate line or a horizontal word line.

The second conductive line DWL may extend in the third direction D3, and the horizontal layer HL may extend in the second direction D2 from the first conductive line BL to the data storage element CAP. The second conductive line DWL may be referred to as a horizontal conductive line. The second conductive line DWL may have a double structure including first and second horizontal conductive lines G1 and G2, which may be referred to as a double horizontal conductive lines, that are facing each other with the horizontal layer HL interposed therebetween. The first horizontal conductive line G1 may be disposed over the horizontal layer HL. The second horizontal conductive line G2 may be disposed below the horizontal layer HL. The first and second horizontal conductive lines G1 and G2 may form a pair of conductive lines coupled to one memory cell MC. A conductive pad (not shown) may be formed between an end of the first horizontal conductive line G1 and an end of the second horizontal conductive line G2 in order to apply the same voltage to the first horizontal conductive line G1 and the second horizontal conductive line G2. The pair of the first and second horizontal conductive lines G1 and G2 may be separated from each other by the horizontal layer HL and a inter-level dielectric layer GD formed on the upper and lower surfaces of the horizontal layer HL.

According to another embodiment of the present invention, different voltages may be applied to the first horizontal conductive line G1 and the second horizontal conductive line G2. For example, a driving voltage may be applied to the first horizontal conductive line G1 while the second horizontal conductive line G2 may be grounded.

In each of the first and second horizontal conductive lines G1 and G2, a width of an overlapping portion that overlaps with the horizontal layer HL (width in the second direction) may be greater than a width of a non-overlapping portion that does not overlap with the horizontal layer HL. Due to this difference in width, the second conductive line DWL may have a notch-shaped sidewall. Referring back to FIG. 1C, the second conductive line DWL may include a channel overlapping portion WLP and a channel non-overlapping portion NOL. The channel overlapping portion WLP may refer to a portion that overlaps with a channel CH of the horizontal layer HL, and the channel non-overlapping portion NOL may refer to a portion that does not overlap with the horizontal layer HL. The channel overlapping portion WLP may have a cross shape or a rhombus shape.

The horizontal layer HL may include a semiconductor material. For example, the horizontal layer HL may include polysilicon, monocrystalline silicon, germanium, or silicon-germanium. According to another embodiment of the present invention, the horizontal layer HL may include an oxide semiconductor material. For example, the oxide semiconductor material may include indium gallium zinc oxide (IGZO).

The horizontal layer HL may include flat upper (also referred to as top) and lower (also referred to as bottom) surfaces. The upper and lower surfaces of the horizontal layer HL may each extend in the second direction and be parallel to each other.

The horizontal layer HL may include a channel CH, a first doped region SR disposed between the channel CH and the first conductive line BL, and a second doped region DR disposed between the channel CH and the data storage element CAP. In some embodiments, the horizontal layer HL may be formed of an oxide semiconductor material, the channel CH may be formed of an oxide semiconductor material, and the first and second doped regions SR and DR may be omitted. The horizontal layer HL may also be referred to as an active layer, or a thin-body layer, or simply a thin-body. The channel CH and the channel overlapping portion WLP of the second conductive line DWL may overlap with each other. The channel CH may have a cross shape as illustrated in FIG. 1A or 1C. However, the shape of the channel CH may vary and in some embodiments, for example, the channel may have a rhombus shape. The size of the channel overlapping portion WLP of the second conductive line DWL may be larger than that of the channel CH. The channel overlapping portion WLP of the second conductive line DWL may fully overlap with the channel CH.

The first and second doped regions SR and DR may be doped with impurities. The impurities may be of the same conductivity type. For example, the first and second doped regions SR and DR may be doped with an N-type impurity or a P-type impurity. The first and second doped regions SR and DR may include at least one impurity selected among arsenic (As), phosphorus (P), boron (B), indium (In), and combinations thereof. The first doped region SR may be coupled to the first conductive line BL. The second doped region DR may be coupled to the first electrode SN of the data storage element CAP. The first and second doped regions SR and DR may be referred to as first and second source/drain regions.

The inter-level dielectric layer GD may be disposed between the horizontal layer HL and the second conductive line DWL. The inter-level dielectric layer GD may be referred to as a gate dielectric layer. The inter-level dielectric layer GD may include silicon oxide, silicon nitride, a metal oxide, a metal oxynitride, a metal silicate, a high-k material, a ferroelectric material, an anti-ferroelectric material or a combination thereof. The inter-level dielectric layer GD may include SiO₂, Si₃N₄, HfO₂, Al₂O₃, ZrO₂, AlON, HfON, HfSiO, HfSiON, or a combination thereof.

The second conductive line DWL may include a metal-based material, a semiconductor material, or a combination thereof. The second conductive line DWL may include titanium nitride, tungsten, polysilicon, or a combination thereof. For example, the second conductive line DWL may include a TiN/W stack in which titanium nitride and tungsten are sequentially stacked. The second conductive line DWL may include an N-type work function material or a P-type work function material. The N-type work function material may have a low work function of approximately 4.5 eV or less, and the P-type work function material may have a high work function of more than 4.5 eV. The second conductive line DWL may include a combination of a work function material and a metal-based material.

The horizontal layer HL of the switching element TR may extend from the top of a lower structure LS in the first horizontal direction D2, and may include a first doped region SR, a channel CH, and a second doped region DR that are sequentially disposed in the first horizontal direction D2. The second conductive line DWL may extend in the second horizontal direction D3 which is orthogonal to the first horizontal direction D2 and may cover the upper and lower surfaces of the channel CH.

The data storage element CAP may be horizontally disposed in the second direction D2 from the switching element TR. The data storage element CAP may include the first electrode SN extending horizontally from the horizontal layer HL in the second direction D2. The data storage element CAP may include the second electrode PN disposed over the first electrode SN with a dielectric layer DE disposed between the first electrode SN and the second electrode PN for electrically separating the first and second electrodes SN and PN. The first electrode SN, the dielectric layer DE, and the second electrode PN may be horizontally arranged in the second directions D2.

From a top view, the first electrode SN may have a rectangular “C” or left bracket “[” shape with with top and bottom bars horizontally extending in the second direction D2 from the main body of the bracket “[” or of the rectangular “C”. The top and bottom bars together with the main body define inner space and a plurality of outer surfaces. The inner space of the first electrode SN may include a a vertical inner surface and two horizontal inner surfaces facing each other. The outer surfaces of the first electrode SN may include a vertical outer surface and a plurality of horizontal outer surfaces. The vertical outer surface of the first electrode SN may extend vertically in the first direction D1 and may be covered with a second contact node SNC (See FIG. 1B). The horizontal outer surfaces of the first electrode SN may extend horizontally in the second or third directions D2 or D3. The inner space of the first electrode SN may be a three-dimensional space. The dielectric layer DE may conformally cover the inner surfaces of the first electrode SN. The second electrode PN may be disposed over the dielectric layer DE to fill the space inside the first electrode SN. At least a part of the outer surface of the first electrode SN may be electrically connected to the second doped region DR of the horizontal layer HL via the second contact node SNC.

The data storage element CAP may have a three-dimensional structure. The first electrode SN may have a 3D structure, and the first electrode SN of the 3D structure may have a horizontal 3D structure which is oriented in the second direction D2. As an example of the 3D structure, the first electrode SN may have a cylinder shape. The cylindrical shape of the first electrode SN may include cylindrical inner surfaces and cylindrical outer surfaces. Some of the cylindrical outer surfaces of the first electrode SN may be electrically connected to the second doped region DR of the horizontal layer HL. The dielectric layer DE and the second electrode PN may be disposed on the cylindrical inner surfaces of the first electrode SN.

According to another embodiment of the present invention, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a tungsten nitride/tungsten (WN/W) stack. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the cylindrical inside of the first electrode SN, and titanium nitride (TIN) may serve as the second electrode PN of a capacitor CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap energy than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material.

According to another embodiment of the present invention, the dielectric layer DE may include a laminated structure in which a high-k material and a high-bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the dielectric layer DE may include a ferroelectric material, an antiferroelectric material, or a combination thereof. The dielectric layer DE may include hafnium zirconium oxide (HfZrO).

According to another embodiment of the present invention, an interface control layer for improving leakage current may be further formed between the first electrode SN and the dielectric layer DE. The interface control layer may include titanium oxide (TiO₂), tantalum oxide (Ta₂O₅), or niobium oxide (Nb₂O₅). The interface control layer may also be formed between the second electrode PN and the dielectric layer DE.

The data storage element CAP may include a Metal-Insulator-Metal (MIM) capacitor. The first electrode SN and the second electrode PN may include a metal-based material.

The data storage element CAP may be replaced with other data storage materials. For example, the data storage material may be a phase change material, a magnetic tunnel junction (MTJ), or a variable resistance material.

Referring again to FIGS. 1A and 1B, the memory cell MC may further include a first contact node BLC, a second contact node SNC, a first capping layer BC, and a second capping layer CC.

The first contact node BLC may surround an outer wall of the first conductive line BL. The second contact node SNC may be disposed between the horizontal layer HL and the first electrode SN. The first capping layer BC may be disposed between the first contact node BLC and the second conductive line DWL. The second capping layer CC may be disposed between the second conductive line DWL and the first electrode SN. The first capping layer BC may have a stacked structure of a first liner L1 and a second liner L2. The first liner L1 may include silicon oxide, and the second liner L2 may include silicon nitride. The second capping layer CC may include silicon oxide, silicon nitride, or a combination thereof. The first capping layer BC and the second capping layer CC may be formed of the same material.

The memory cell MC may further include an extension portion BE disposed between the first contact node BLC and the horizontal layer HL. The extension portion BE may include a semiconductor material. The extension portion BE may include undoped polysilicon or doped polysilicon. The extension portion BE may include a conductive material. The extension portion BE and the first doped region SR may include impurities diffused from the first contact node BLC. According to another embodiment of the present invention, the extension portion BE may be referred to as a contact node extension portion.

The memory cell MC may further include a blocking layer BR disposed between the first contact node BLC and the first capping layer BC. The blocking layer BR may selectively grow from the surface of the first capping layer BC. The blocking layer BR may include a dielectric material. The blocking layer BR may include silicon carbon oxide (SiCO). The blocking layer BR may selectively grow from the surface of the second liner L2 of the first capping layer BC. As will be described later, the blocking layer BR may grow by an area selective deposition (ASD) method. The blocking layer BR may include ASD-SiCO. ASD-SiCO may refer to silicon carbon oxide (SiCO) which is deposited by the ASD method.

As described earlier, as the blocking layers BR are formed, a bridge between the second conductive lines DWL and the first conductive line BL may be prevented from being formed.

According to a comparative example, when the blocking layers BR are omitted, the second conductive lines DWL and the first conductive line BL may be electrically bridged due to fume originating from the second conductive lines DWL and seams originating from the first capping layer BC.

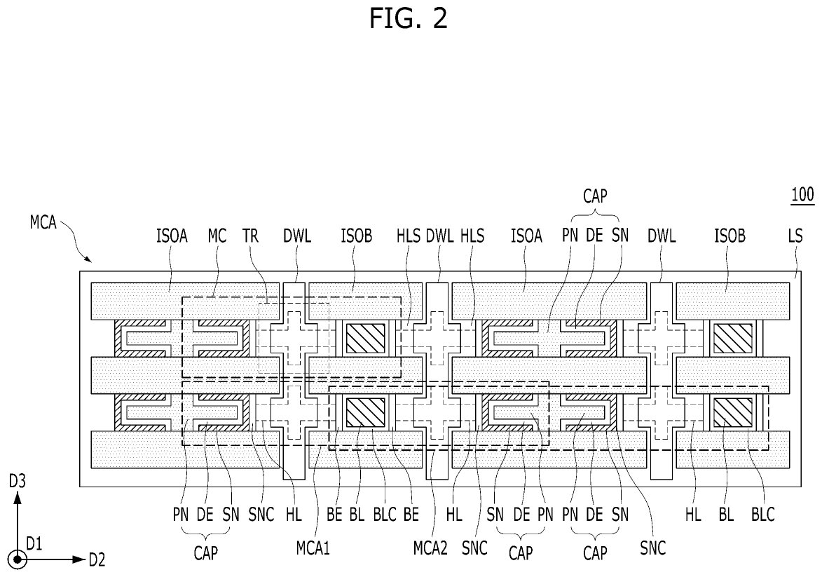

FIG. 2 is a schematic plan view illustrating a semiconductor device in accordance with an embodiment of the present invention. FIG. 3A is a schematic perspective view illustrating a first memory cell array MCA1 shown in FIG. 2. FIG. 3B is a schematic cross-sectional view illustrating the first memory cell array MCA1 shown in FIG. 2.

Referring to FIGS. 2, 3A, and 3B, the semiconductor device 100 may include a memory cell array MCA. The memory cell array MCA may include a plurality of memory cells MC. As for the description on the individual memory cells MC, FIGS. 1A to 1C may be referred to.

The memory cell array MCA may include a three-dimensional array of memory cells MC. The 3D array of memory cells MC may include a column array of memory cells MC and a row array of memory cells MC. In the column array of memory cells MC, a plurality of memory cells MC may be stacked in the first direction D1, and in the row array of memory cells MC, a plurality of memory cells MC may be horizontally arranged in the second and third directions D2 and D3. The memory cell array MCA may include a first memory cell array MCA1 and a second memory cell array MCA2 that are adjacent to each other in the second direction D2. The first memory cell array MCA1 may have a mirror-type structure in which two memory cells MC share a first conductive line BL. The second memory cell array MCA2 may have a mirror-type structure in which two memory cells MC share the second electrode PN of the data storage element CAP. The memory cell array MCA may include a plurality of first memory cell arrays MCA1 and a plurality of second memory cell arrays MCA2.

According to some embodiments of the present invention, inter-cell dielectric layers IL may be disposed between the memory cells MC stacked in the first direction D1. Cell isolation layers ISOA and ISOB may be disposed between the neighboring memory cells MC in the third direction D3. The cell isolation layers ISOA and ISOB may include silicon oxide, silicon carbon oxide (SiCO), silicon nitride, or a combination thereof. The cell isolation layers ISOA and ISOB may include first cell isolation layers ISOA and second cell isolation layers ISOB. The first cell isolation layers ISOA and the second cell isolation layers ISOB may extend vertically in the first direction D1. The first cell isolation layers ISOA and the second cell isolation layers ISOB may be alternately and repeatedly disposed in the second direction D2. The first cell isolation layers ISOA may be disposed between the data storage elements CAP in the third direction D3. The second cell isolation layers ISOB may be disposed between the first conductive lines BL in the third direction D3. The second conductive line DWL may be disposed between the first cell isolation layers ISOA and the second cell isolation layers ISOB in the second direction D2.

The memory cell array MCA may be disposed over the lower structure LS.

Each memory cell MC may include a first conductive line BL, a switching element TR, and a data storage element CAP. The switching element TR may include a horizontal layer HL, a inter-level dielectric layer GD, and a second conductive line DWL. The data storage element CAP may include a memory element, such as, for example, a capacitor. The first conductive line BL may include a bit line. The second conductive line DWL may include a word line, and the horizontal layer HL may include an active layer. The data storage element CAP may include a first electrode SN, a dielectric layer DE, and a second electrode PN. The switching element TR may include a transistor, and in this case, the second conductive line DWL may serve as a gate electrode. The switching element TR may also be referred to as a cell transistor, an access element, or a selection element.

The memory cell array MCA may include a plurality of second conductive lines DWL vertically stacked in the first direction D1. The memory cell array MCA may include a plurality of horizontal layers HL vertically stacked in the first direction D1. The memory cell array MCA may include a plurality of data storage elements CAP vertically stacked in the first direction D1.

A plurality of first buffer layers BF1 may be disposed between the lowermost second conductive line DWL among the second conductive lines DWL and the lower structure LS. A cell isolation layer IL may be disposed between the lowermost second conductive line DWL and a first buffer layer BF1.

A second buffer layer BF2 may be disposed between the first conductive line BL and the lower structure LS. Third buffer layers BF3 may be disposed between the data storage element CAP and the lower structure LS. The first to third buffer layers BF1, BF2, and BF3 may include a dielectric material. For example, the first to third buffer layers BF1, BF2, and BF3 may include silicon oxide. The first conductive line BL, the second conductive lines DWL, and the first to third buffer layers BF1, BF2, and BF3 may electrically disconnect the data storage elements CAP from the lower structure LS. The first conductive line BL may extend into the lower structure LS. The dielectric layer DE and the second electrode PN of the data storage element CAP may extend into the lower structure LS.

The first conductive line BL may extend vertically from the top of the lower structure LS in the first direction D1. The horizontal layers HL may extend in the second direction D2 crossing the first direction D1. The second conductive lines DWL may extend in the third direction D3 crossing the first and second directions D1 and D2.

Each of the second conductive lines DWL may include a channel overlapping portion WLP, which is illustrated in FIG. 1C. The channel overlapping portion WLP may have a cross shape or a rhombus shape. The channel overlapping portion WLP may fully overlap with the channel CH. The second conductive line DWL extending in the third direction D3 may include a plurality of channel overlapping portions WLP, and the second conductive line DWL may have a notched sidewall due to the channel overlapping portions WLP. The channel overlapping portions WLP and channel non-overlapping portions may be alternately disposed in the third direction D3. The channel overlapping portion WLP may have a cross shape or a rhombus shape.

From the perspective of a top view, the horizontal layers HL may have a cross shape or a rhombus shape. According to another embodiment of the present invention, side surfaces of the horizontal layer HL may have a bent shape or a round shape. Horizontal layer level spacers HLS may be disposed on the sidewalls of the horizontal layers HL. The horizontal layers HL disposed in the third direction D3 may be electrically disconnected by the horizontal layer level spacers HLS. The horizontal layer HL may include a channel CH, a first doped region SR between the channel CH and the first conductive line BL, and a second doped region DR between the channel CH and the data storage element CAP. The channel CH may have a cross shape or a rhombus shape.

A first capping layer BC may be disposed between the second conductive line DWL and the first conductive line BL. A second capping layer CC may be disposed between the second conductive line DWL and the first electrode SN of the data storage element. The first capping layer BC may be disposed between the first horizontal conductive line G1 and the first conductive line BL, and the first capping layer BC may be disposed between the second horizontal conductive line G2 and the first conductive line BL. The second capping layer CC may be disposed between the first horizontal conductive line G1 and the first electrode SN of the data storage element CAP, and the second capping layer CC may be disposed between the second horizontal conductive line G2 and the first electrode SN of the data storage element CAP.

The first and second capping layers BC and CC may include a dielectric material. The first and second capping layers BC and CC may include silicon oxide, silicon nitride, silicon carbon oxide, an air gap, or a combination thereof. The first capping layer BC may include silicon oxide, and the second capping layer CC may include a stack of silicon oxide and silicon nitride.

Referring to FIG. 1B, the first capping layer BC may have a stacked structure of a first liner L1 and a second liner L2. The first liner L1 may include silicon oxide, and the second liner L2 may include silicon nitride.

Each memory cell MC may further include an extension portion BE disposed between the first contact node BLC and the horizontal layer HL. The extension portion BE may include a semiconductor material. For example, the extension portion BE may include undoped polysilicon or doped polysilicon. The extension portion BE may include a conductive material. The extension portion BE and the first doped region SR may include impurities diffused from the first contact node BLC.

Each memory cell MC may further include a blocking layer BR disposed between the first contact node BLC and the first capping layer BC. The blocking layer BR may selectively grow from the surface of the first capping layer BC. The blocking layer BR may include a dielectric material. The blocking layer BR may include silicon carbon oxide (SiCO). The blocking layer BR may selectively grow from the surface of the second liner L2 of the first capping layer BC. As will be described later, the blocking layer BR may grow by the area selective deposition (ASD) method. The blocking layer BR may include ASD-SiCO may refer to silicon carbon oxide include ASD-SiCO. (SiCO) deposited by the ASD method.

The memory cell array MCA may have a mirror-type structure sharing the first conductive line BL.

The second electrodes PN of the data storage elements CAP may be coupled to a common plate PL. The horizontal layers HL of the switching elements TR disposed horizontally in the third direction D3 may share one second conductive line DWL. The horizontal layers HL of the switching elements TR disposed horizontally in the third direction D3 may be coupled to different first conductive lines BL. The switching elements TR stacked in the first direction D1 may share one first conductive line BL. The switching elements TR disposed horizontally in the third direction D3 may share one second conductive line DWL.

The lower structure LS may include a semiconductor substrate, a metal line structure, a dielectric structure, a conductive structure, a bonding pad structure, another memory or a peripheral circuit unit.

For example, the lower structure LS may include a structure in which a peripheral circuit unit, a metal line structure, and a bonding pad structure are sequentially stacked. The memory cell array MCA and the lower structure LS may be coupled by wafer bonding.

A peripheral circuit unit of the lower structure LS may be disposed at a level lower than that of the memory cell array MCA. This may be referred to as a Cell-Over-Peripheral (COP) structure. The peripheral circuit unit may include at least one control circuit for driving the memory cell array MCA. The at least one control circuit of the peripheral circuit unit may include an N-channel transistor, a P-channel transistor, a CMOS circuit, or a combination thereof. The at least one control circuit of the peripheral circuit unit may include an address decoder circuit, a read circuit, a write circuit, and the like. The at least one control circuit of the peripheral circuit unit may include a planar channel transistor, a recess channel transistor, a buried gate transistor, a fin channel transistor (FinFET), and the like.

For example, the peripheral circuit unit may include sub-word line drivers and a sense amplifier. The second conductive lines DWL may be coupled to the sub-word line drivers. The first conductive line BL may be coupled to the sense amplifier.

According to another embodiment of the present invention, the peripheral circuit unit may be disposed at a higher level than that of the memory cell array MCA. This may be referred to as a Peripheral-Over-Cell (POC) structure.

According to another embodiment of the present invention, the memory cell array MCA may include a Dynamic Random Access Memory (DRAM), an embedded DRAM, a NAND memory, a ferroelectric RAM (FeRAM), a Spin-Transfer Torque RAM (STTRAM), a Phase-Change RAM (PCRAM), or a Resistive RAM (ReRAM).

According to FIGS. 2, 3A, and 3B, the semiconductor device 100 may include a lower structure LS, a plurality of horizontal layers HL horizontally oriented in the second direction D2 which is parallel to the surface of the lower structure LS, a first conductive line BL commonly coupled to first ends of the horizontal layers HL and extend in the first direction D1 which is perpendicular to the surface of the lower structure LS, a plurality of second conductive lines DWL crossing the horizontal layers HL, a plurality of data storage elements CAP respectively coupled to the second ends of the horizontal layers HL and vertically stacked over the lower structure LS, a first capping layer BC disposed between the second conductive lines DWL and the first conductive line BL, and a blocking layer BR disposed between the first capping layer BC and the first conductive line BL. The first capping layer BC may include a first liner L1 and a second liner L2 partially surrounded by the first liner L1, and the blocking layer BR may include a material selectively deposited from the surface of the second liner L2. For example, the first liner L1 may include silicon oxide, and the second liner L2 may include silicon nitride, and the blocking layer BR may include silicon carbon oxide. As the blocking layers BR are formed, a bridge between the second conductive lines DWL and the first conductive lines BL may be prevented from being formed.

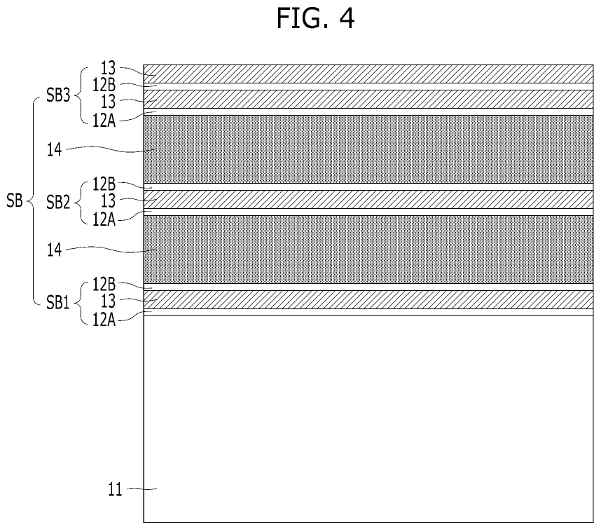

FIGS. 4 to 24 illustrate an example of a method for fabricating a semiconductor device in accordance with an embodiment of the present invention.

Referring to FIG. 4, a stack body SB may be formed over the lower structure 11. The lower structure 11 may include a semiconductor substrate. In the stack body SB, a plurality of sub-stacks may be alternately stacked. Each of the sub-stacks may include a first layer 12A, a second layer 13, a third layer 12B and a semiconductor layer 14 that are stacked in the mentioned order. The first layer 12A and the third layer 12B may be formed of the same material. The first layer 12A, the second layer 13 and the third layer 12B may include a sacrificial material that is removed in a subsequent process. Hereinafter, the first and third layers 12A and 12B may be simply referred to as first and second sacrificial layers 12A and 12B, and the second layer 13 may be simply referred to as a sacrificial semiconductor layer 13.

Each of the sub-stacks may include a first sacrificial layer 12A, a sacrificial semiconductor layer 13, a second sacrificial layer 12B, and a semiconductor layer 14 that are stacked in the mentioned order. The first and second sacrificial layers 12A and 12B may include silicon germanium, and the sacrificial semiconductor layers 13 may include monocrystalline silicon. The semiconductor layer 14 may include monocrystalline silicon. The first sacrificial layer 12A, the sacrificial semiconductor layer 13, the second sacrificial layer 12B, and the semiconductor layer 14 may be formed by an epitaxial growth process. The first and second sacrificial layers 12A and 12B may be thinner than the sacrificial semiconductor layer 13, and the semiconductor layer 14 may be thicker than the sacrificial semiconductor layer 13.

The stack body SB may include a plurality of semiconductor layers 14, a first sacrificial layer structure SB1, a second sacrificial layer structure SB2, and a third sacrificial layer structure SB3. In the stack body SB, a first sacrificial layer structure SB1, a semiconductor layer 14, a second sacrificial layer structure SB2, a semiconductor layer 14, and a third sacrificial layer structure SB3 may be stacked in the mentioned order. A sacrificial semiconductor layer 13 may be disposed in the uppermost layer of the stack body SB. Each of the first sacrificial layer structure SB1, the second sacrificial layer structure SB2, and the third sacrificial layer structure SB3 may include a triple layer stack of the first sacrificial layer 12A/the sacrificial semiconductor layer 13/the second sacrificial layer 12B. The sacrificial semiconductor layer 13 may be disposed in the uppermost layer of the third sacrificial layer structure SB3. For example, when the first and second sacrificial layers 12A and 12B include a silicon germanium layer and the sacrificial semiconductor layer 13 includes a monocrystalline silicon layer, each of the first sacrificial layer structure SB1, the second sacrificial layer structure SB2, and the third sacrificial layer structure SB3 may include a stack (SiGe/Si/SiGe) of a first silicon germanium layer/a monocrystalline silicon layer/a second silicon germanium layer.

The sacrificial semiconductor layer 13 may include a first monocrystalline silicon layer, and the semiconductor layer 14 may include a second monocrystalline silicon layer. Accordingly, in the stack body SB, the first sacrificial layer structure SB1 may be disposed below the second monocrystalline silicon layer, and the second sacrificial layer structure SB2 may be disposed over the second monocrystalline silicon layer. Each of the first and second sacrificial layer structures SB1 and SB2 may include a stack of the first silicon germanium layer/the first monocrystalline silicon layer/the second silicon germanium layer. The second monocrystalline silicon layer may be thicker than the first monocrystalline silicon layer.

According to the embodiments of the present invention described above, when memory cells are stacked, the first sacrificial layer structure SB1, the semiconductor layer 14, the second sacrificial layer structure SB2, the semiconductor layer 14, and the third sacrificial layer structure SB3 may be alternately stacked several times.

According to another embodiment of the present invention, in the stack body SB, the first sacrificial layers 12A and the semiconductor layers 14 may be alternately stacked. For example, in the stack body SB, a plurality of silicon germanium layers and a plurality of monocrystalline silicon layers may be alternately stacked. The silicon germanium layers and the monocrystalline silicon layers may be formed by an epitaxial growth process, and the silicon germanium layers and the monocrystalline silicon layers may have the same thickness. The stack body SB may include a SiGe/Si/SiGe/Si stack.

Subsequently, as illustrated in FIGS. 2 to 3A and 3B, cell isolation layers ISOA and ISOB may be formed. The cell isolation layers ISOA and ISOB may be formed in the stack body SB.

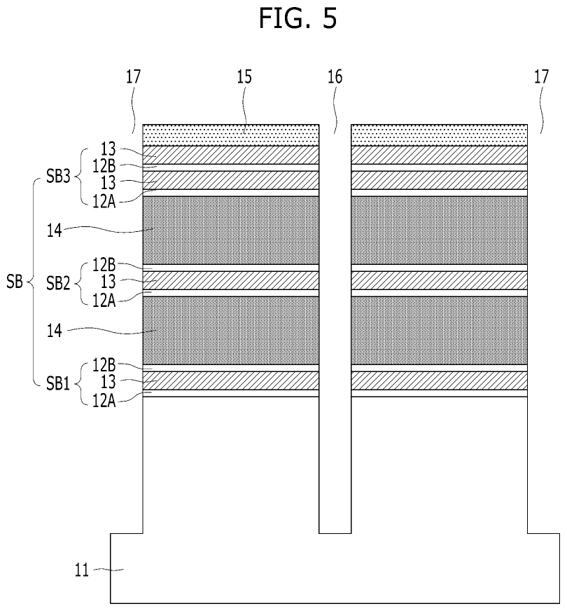

Referring to FIG. 5, a hard mask layer 15 may be formed over the stack body SB. The hard mask layer 15 may include silicon nitride.

Subsequently, a plurality of vertical openings 16 and 17 penetrating the stack body SB may be formed. The stack body SB may be etched to form the vertical openings 16 and 17. The vertical openings 16 and 17 may include first vertical openings 16 and second vertical openings 17. The vertical openings 16 and 17 may be hole-type openings. From the perspective of a top view, the cross section of the vertical openings 16 and 17 may be circular, rectangular or polygonal.

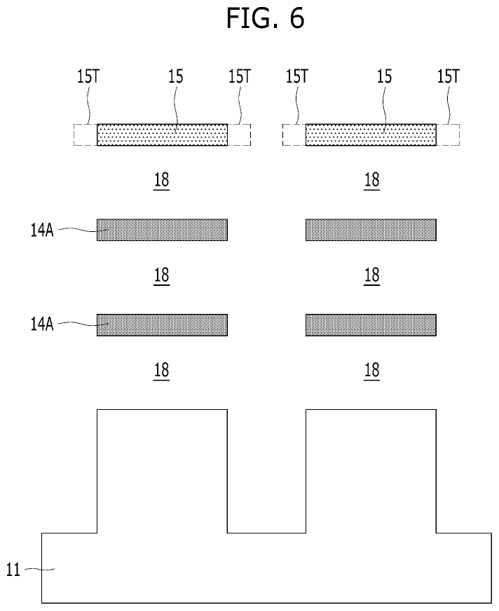

Referring to FIG. 6, a portion of the hard mask layer 15 may be trimmed (refer to a reference numeral 15T).

Subsequently, the first and second sacrificial layers 12A and 12B may be selectively removed through the vertical openings 16 and 17. In order to selectively remove the first and second sacrificial layers 12A and 12B, a difference in the etch selectivity between the sacrificial semiconductor layers 13 and the first and second sacrificial layers 12A and 12B may be used. Also, in order to selectively remove the first and second sacrificial layers 12A and 12B, the difference in the etch selectivity between the semiconductor layers 14 and the first and second sacrificial layers 12A and 12B may be used. The first and second sacrificial layers 12A and 12B may be removed by a wet etching process or a dry etching process. For example, when the first and second sacrificial layers 12A and 12B include a silicon germanium layer and the sacrificial semiconductor layers 13 and the semiconductor layers 13 and 14 include a silicon layer, the silicon germanium layers may be etched using an etchant or an etching gas having a selectivity with respect to the silicon layers.

Subsequently, the sacrificial semiconductor layers 13 and the semiconductor layers 14 may be recessed. In order to recess the sacrificial semiconductor layers 13 and the semiconductor layers 14, a wet etching process or a dry etching process may be used. According to this embodiment of the present invention, the sacrificial semiconductor layers 13 may be removed, and the semiconductor layers 14 may be partially etched. Since the sacrificial semiconductor layers 13 and the semiconductor layers 14 are formed of the same material, the semiconductor layers 14 may become thin as indicated by a reference numeral 14A, while the sacrificial semiconductor layers 13 is removed. A recess process for forming the thin semiconductor layer 14A, that is, the semiconductor layer patterns 14A, may be referred to as a thinning process or a trimming process of the semiconductor layers 14. The semiconductor layer patterns 14A may be referred to as a thin-body active layer. The semiconductor layer patterns 14A may include a monocrystalline silicon layer. While the semiconductor layer patterns 14A are formed, the surface of the lower structure 11 may be recessed to a predetermined depth.

Through the above-described recess process, the semiconductor layer patterns 14A may be formed, and horizontal recesses 18 may be defined between the semiconductor layer patterns 14A. Each of the upper and lower surfaces of the semiconductor layer patterns 14A may include a flat surface.

From the perspective of a top view, the semiconductor layer patterns 14A may have a cross shape. The side surfaces of the semiconductor layer patterns 14A may have a bent shape or a round shape.

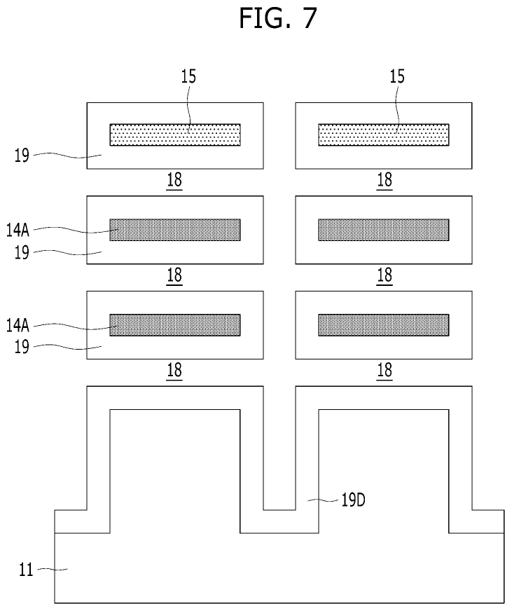

Referring to FIG. 7, sacrificial dielectric layers 19 surrounding or fully covering the semiconductor layer patterns 14A may be formed. The sacrificial dielectric layers 19 may include silicon nitride.

While the sacrificial dielectric layers 19 are formed, a dummy sacrificial dielectric layer 19D may be formed on the surface of the lower structure 11. The dummy sacrificial dielectric layer 19D and the sacrificial dielectric layers 19 may be formed of the same material. The dummy sacrificial dielectric layer 19D may include silicon nitride.

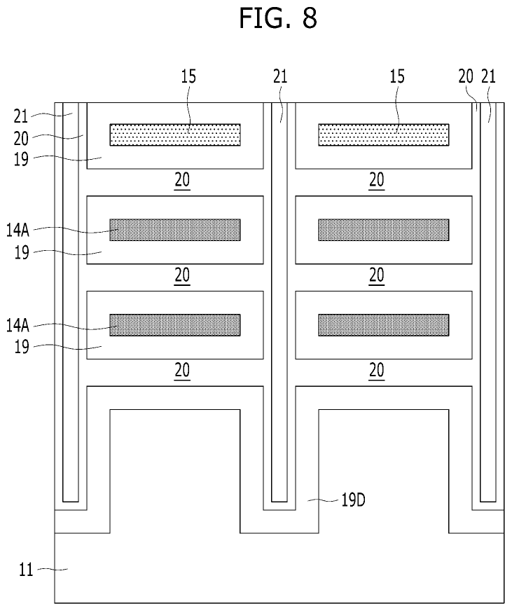

Referring to FIG. 8, an inter-cell dielectric layer 20 may be formed over the sacrificial dielectric layers 19. The inter-cell dielectric layer 20 may fill between the sacrificial dielectric layers 19 that are vertically adjacent to each other. The inter-cell dielectric layer 20 may include silicon oxide. Portions of the inter-cell dielectric layer 20 may be conformally formed on the surfaces of the vertical openings 16 and 17.

Subsequently, a sacrificial pillar 21 may be formed over the inter-cell dielectric layer 20 that is disposed in the vertical openings 16 and 17. The sacrificial pillar 21 may include amorphous carbon. According to another embodiment of the present invention, a pillar capping layer may be further formed over the sacrificial pillar 21. The pillar capping layer may include a metal-based material. The pillar capping layer, for example, may include titanium nitride.

The inter-cell dielectric layer 20 and the sacrificial pillar 21 may form a sacrificial pillar structure filling the vertical openings 16 and 17. The sacrificial pillars 21 may not be formed between the sacrificial dielectric layers 19 that are vertically stacked. The sacrificial pillar structure may include a dielectric material, a carbon-containing material, a metal-based material, or a combination thereof. The sacrificial pillar structure may include silicon oxide, silicon nitride, titanium nitride, amorphous carbon, or a combination thereof.

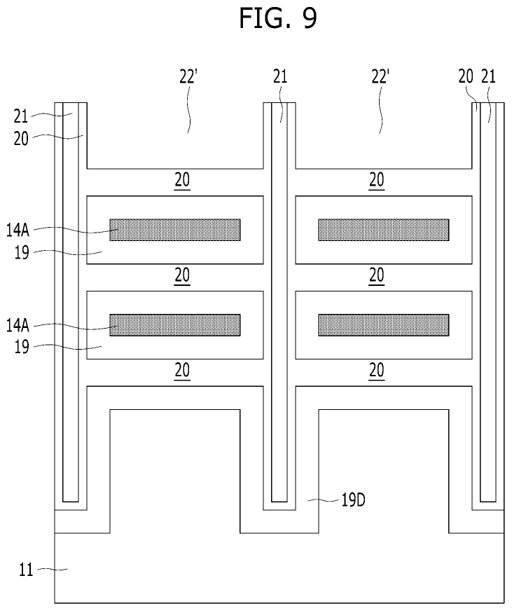

Referring to FIG. 9, a hard mask layer level opening 22′ may be formed by removing the hard mask layer 15 and the uppermost level sacrificial dielectric layer 19.

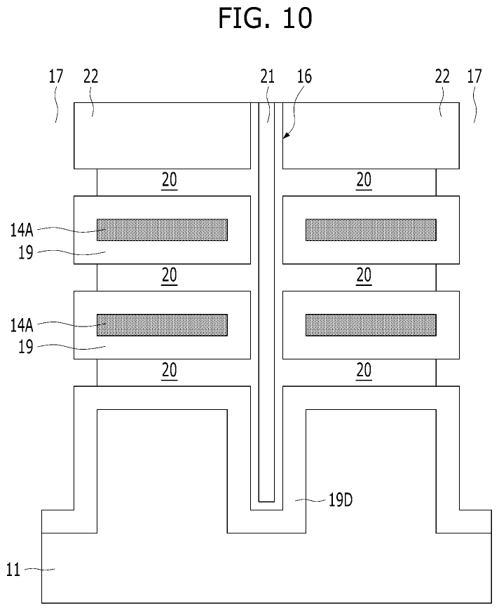

Referring to FIG. 10, a top dielectric layer 22 filling the hard mask layer level opening 22′ may be formed. The top dielectric layer 22 may be formed by a deposition process of silicon oxide and a Chemical Mechanical Polishing (CMP) process.

Subsequently, in order to expose the second vertical openings 17 among the first and second vertical openings 16 and 17, the inter-cell dielectric layer 20 and the sacrificial pillar 21 may be removed.

The sacrificial dielectric layers 19 and the dummy sacrificial dielectric layer 19D may be exposed by the second vertical openings 17.

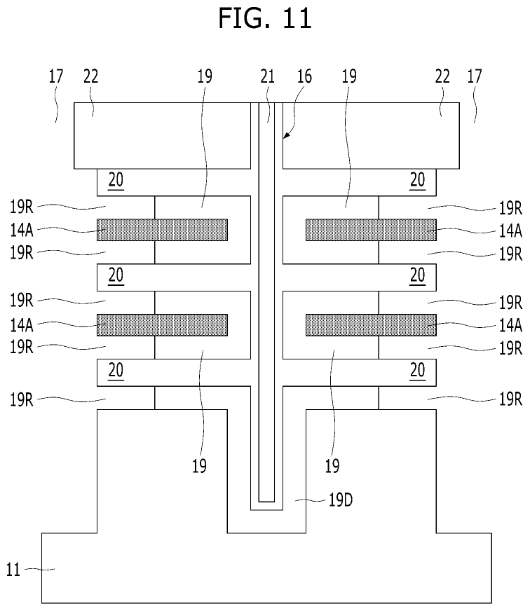

Referring to FIG. 11, the sacrificial dielectric layers 19 and the dummy sacrificial dielectric layer 19D may be selectively horizontally recessed. Accordingly, sacrificial dielectric layer level recesses 19R may be formed. Portions of the semiconductor layer patterns 14A may be exposed by the sacrificial dielectric layer level recesses 19R.

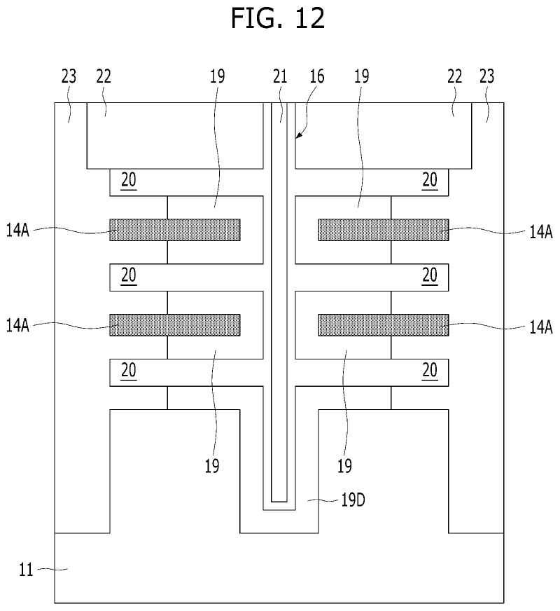

Referring to FIG. 12, a vertical level sacrificial structure 23 filling the second vertical openings 17 may be formed. The vertical level sacrificial structure 23 may include a dielectric material. The vertical level sacrificial structure 23 may include silicon oxide, silicon nitride, or a combination thereof. For example, the vertical level sacrificial structure 23 may have a stacked structure of a silicon oxide liner and silicon nitride.

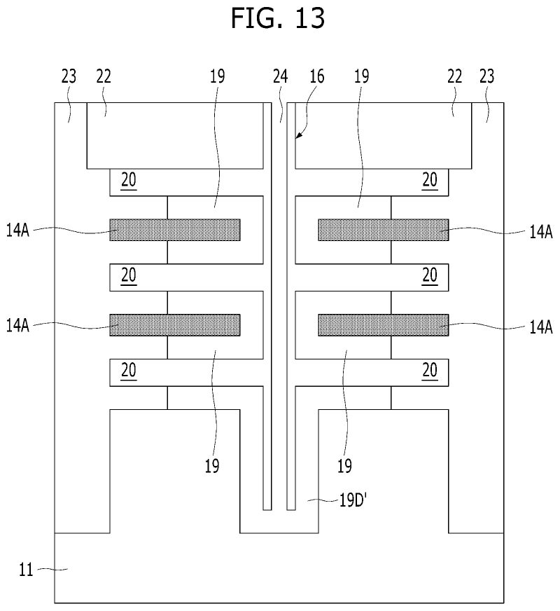

Referring to FIG. 13, in order to form a first hole-type opening 24, the sacrificial pillar 21 filling the first vertical opening 16 may be removed.

Subsequently, in order to form a lower-level gap 19D′, the dummy sacrificial layer 19D below the first hole-type opening 24 may be removed.

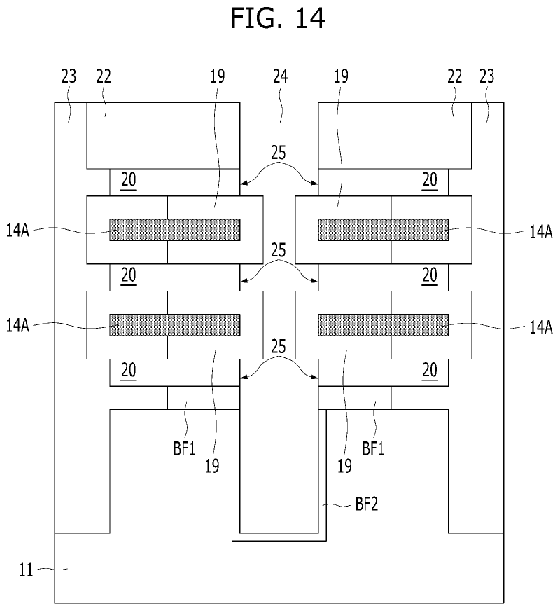

Referring to FIG. 14, in order to expand the first hole-type opening 24, the cell isolation layers 20 may be cut (see 25).

Subsequently, a first buffer layer BF1 filling the lower-level gap 19D′ may be formed. The first buffer layer BF1 may include silicon oxide. Forming the first buffer layer BF1 may include depositing silicon oxide filling the lower-level gap 19D′ and etching the silicon oxide. Subsequently, the surface of the lower structure 11 may be oxidized to form the second buffer layer BF2. The second buffer layer BF2 may include silicon oxide.

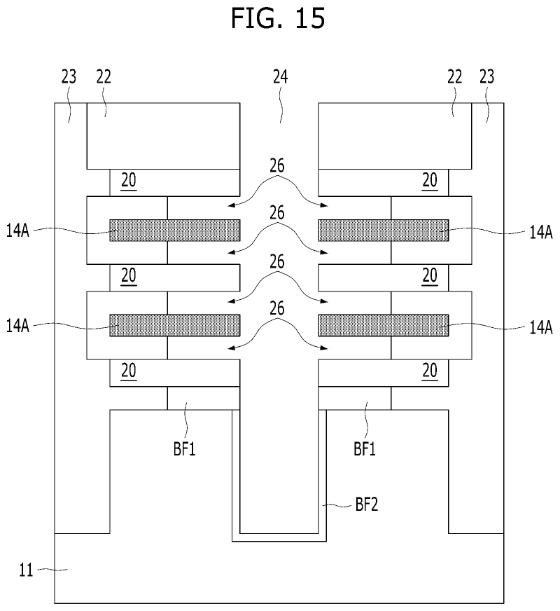

Referring to FIG. 15, to form the horizontal level recesses 26, the sacrificial dielectric layers 19 may be removed. Portions of the semiconductor layers 14A may be exposed by the horizontal level recesses 26.

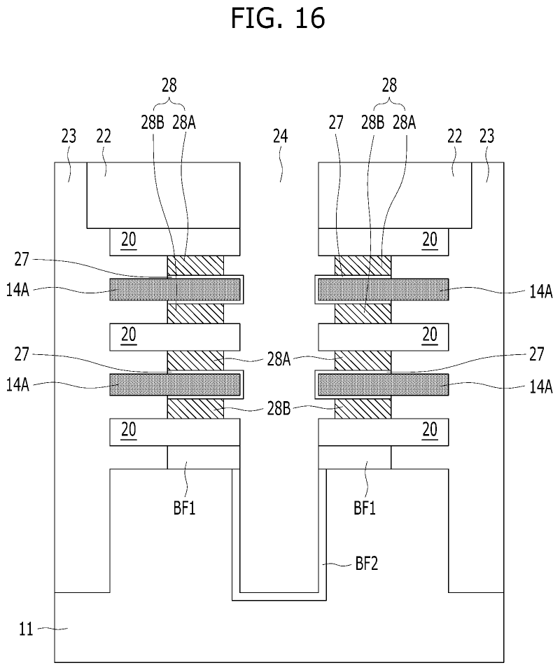

Referring to FIG. 16, a inter-level dielectric layer 27 may be formed over the exposed portions of the semiconductor layer patterns 14A. The inter-level dielectric layer 27 may be formed by oxidizing the surface of the semiconductor layer patterns 14A. According to another embodiment of the present invention, the inter-level dielectric layer 27 may be formed by a process of depositing silicon oxide.

The inter-level dielectric layer 27 may include silicon oxide, silicon nitride, a metal oxide, a metal oxynitride, a metal silicate, a high-k material, a ferroelectric material, an anti-ferroelectric material, or a combination thereof. The inter-level dielectric layer 27 may include SiO₂, Si₃N₄, HfO₂, Al₂O₃, ZrO₂, AlON, HfON, HfSiO, HfSiON, or a combination thereof.

Subsequently, horizontal conductive lines 28 filling the horizontal level recesses 26 may be formed over the inter-level dielectric layer 27. Forming the horizontal conductive line 28 may include depositing a conductive material filling the horizontal level recesses 26 over the inter-level dielectric layer 27, and performing an etch-back process on the conductive material. The horizontal conductive line 28 may include a pair of first and second horizontal conductive lines 28A and 28B that are facing each other with the semiconductor layer pattern 14A therebetween. The first and second horizontal conductive lines 28A and 28B may include a metal-based material, a semiconductor material, or a combination thereof. The first and second horizontal conductive lines 28A and 28B may include titanium nitride, tungsten, polysilicon, or a combination thereof. For example, the first and second horizontal conductive lines 28A and 28B may include a TiN/W stack in which titanium nitride and tungsten are sequentially stacked. The first and second horizontal conductive lines 28A and 28B may include an N-type work function material or a P-type work function material. The N-type work function material may have a low work function of approximately 4.5 eV or less, and the P-type work function material may have a high work function of approximately 4.5 eV or more.

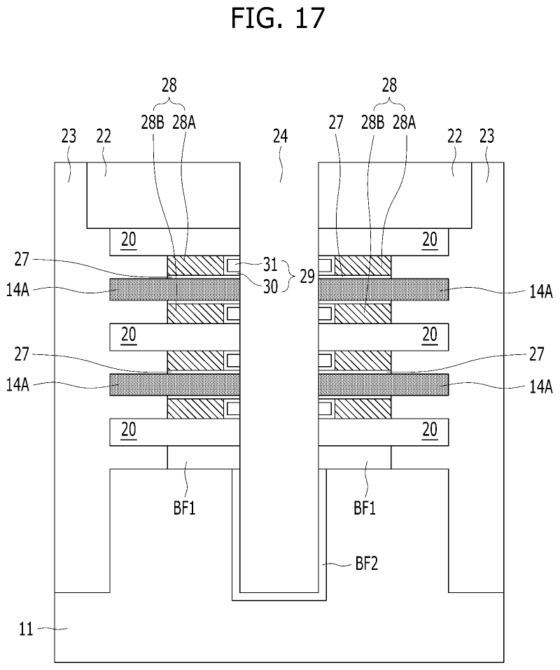

Referring to FIG. 17, a first capping layer 29 may be formed on a first side of the horizontal conductive line 28. The first capping layer 29 may include silicon oxide, silicon nitride, or a combination thereof. A capping material may be deposited and etched back to form the first capping layer 29. While or after the first capping layer 29 is formed, a portion of the inter-level dielectric layer 27 may be removed to expose a first edge portion of each of the semiconductor layer patterns 14A.

The first capping layer 29 may include a stack of a first liner 30 and a second liner 31. The first liner 30 may include silicon oxide, and the second liner 31 may include silicon nitride. The first liner 30 may be conformally formed, and the second liner 31 may be thicker than the first liner 30.

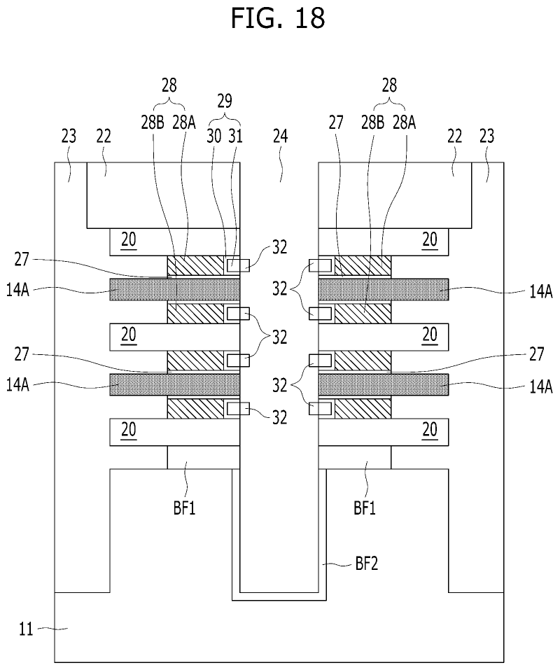

Referring to FIG. 18, blocking layers 32 may be formed over the first capping layers 29, respectively. The blocking layer 32 may be formed by an Area Selective Deposition (ASD) process. For example, when the ASD method is applied, the blocking layer 32 may be selectively deposited over the second liner 31, and the blocking layer 32 may not be formed over the first liner 30, the inter-cell dielectric layer 20, and the semiconductor layer pattern 14A. The blocking layer 32 may not be formed over the first buffer layer BF1 and the second buffer layer BF2.

The blocking layer 32 may include silicon carbon oxide (SiCO) by the ASD process, that is, ASD-SiCO. Since the second liner 31 is silicon nitride, ASD-SiCO may be selectively deposited over the silicon nitride. The ASD process is a method of reducing the deposition rate only on the specific surfaces by using an inhibitor. For example, when silicon carbon oxide is deposited by the ASD process, the deposition may be suppressed on the surfaces of the first liner 30, the inter-cell dielectric layer 20, and the semiconductor layer patterns 14A, and silicon carbon oxide may be deposited on the surface of the second liner 31.

An example of a method of depositing silicon carbon oxide by the ASD process may include forming silicon carbon oxide selectively on silicon nitride among silicon oxide and silicon nitride by using an aminosilane-based inhibitor. The aminosilane-based inhibitor may be selectively adsorbed on the surface of silicon oxide among silicon oxide and silicon nitride. The aminosilane-based inhibitor may include Diisopropylaminosilane (DIPAS). Deposition of silicon carbon oxide may be suppressed on the silicon oxide to which the aminosilane-based inhibitor is adsorbed, and silicon carbon oxide may be selectively deposited only on the silicon nitride to which the aminosilane-based inhibitor is not adsorbed.

According to another embodiment of the present invention, the blocking layer 32 may be formed by repeating the deposition and etching of silicon carbon oxide several times. First, silicon carbon oxide may be thinly deposited on the silicon oxide to which the aminosilane-based inhibitor is adsorbed, and silicon carbon oxide may be deposited thick on the silicon nitride to which the aminosilane-based inhibitor is not adsorbed. Subsequently, an etching process of etching silicon carbon oxide may be performed. During the etching process of silicon carbon oxide, the thin silicon carbon oxide may be removed from the upper portion of the silicon oxide, and the thin silicon carbon oxide may remain over the silicon oxide.

The thickness of the second liner 31 may be reinforced by the blocking layer 32. The blocking layer 32 may have a thickness of approximately 15 to 20 nm.

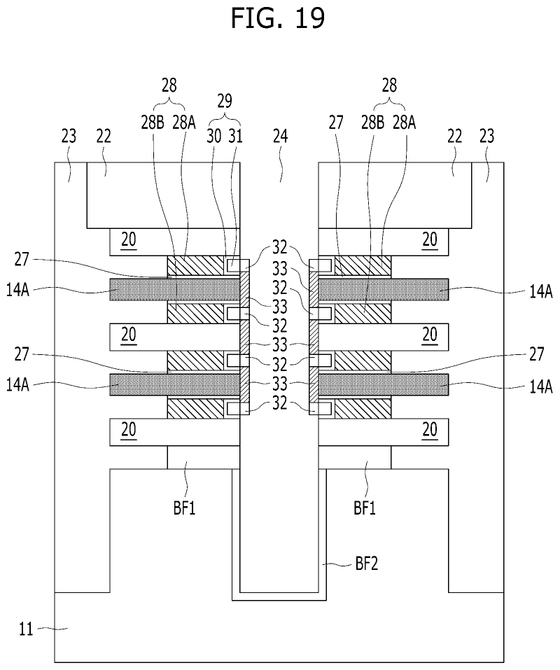

Referring to FIG. 19, extension portions 33 may be formed between the vertically disposed blocking layers 32. To form the extension portions 33, a deposition process of polysilicon and an etch-back process may be performed. The extension portions 33 may be disposed on first sides of the semiconductor layer patterns 14A and first sides of the cell isolation layers 20. The extension portions 33 may also include undoped polysilicon.

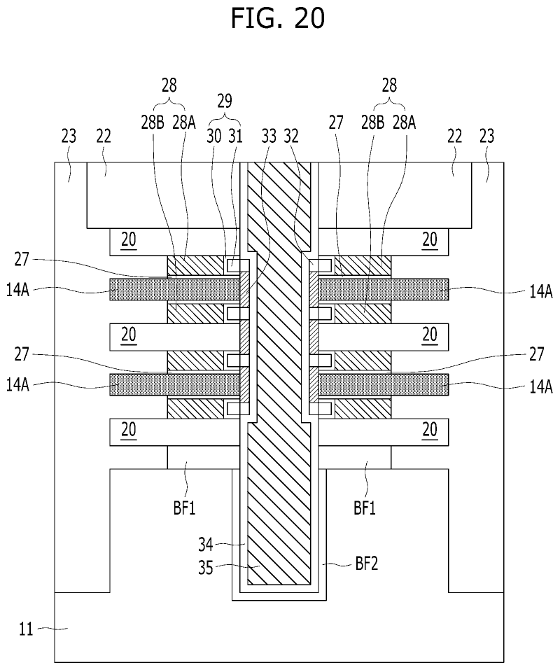

Referring to FIG. 20, a vertical conductive line 35 coupled to a first edge portion of each of the semiconductor layer patterns 14A may be formed. The vertical conductive line 35 may fill the first hole-type opening 24. The vertical conductive line 35 may be commonly coupled to the semiconductor layer patterns 14A. The vertical conductive line 35 may include titanium nitride, tungsten, or a combination thereof. The vertical conductive line 35 may include a bit line.

Prior to forming the vertical conductive line 35, a first contact node 34 may be conformally formed over the first hole-type opening 24. The first contact node 34 may include doped polysilicon. After the first contact node 34 is formed, an annealing process may be performed subsequently. Accordingly, the extension portions 33 may include impurities diffused from the first contact node 34.

According to another embodiment of the present invention, referring to FIG. 1B, a first doped region SR may be formed in the first edge portions of the semiconductor layer patterns 14A. Forming the first doped region SR may include depositing polysilicon that is doped with an N-type impurity, performing a heat treatment process, and removing the doped polysilicon. The first doped region SR may include an impurity diffused from doped polysilicon. According to another embodiment of the present invention, the first doped region SR may be formed by a process of doping an impurity. The first doped region SR may include an impurity to be diffused from the first contact node 34.

As described above, as the blocking layers 32 are formed, a bridge of the horizontal conductive lines 28 and the vertical conductive lines 35 may be prevented from being formed.

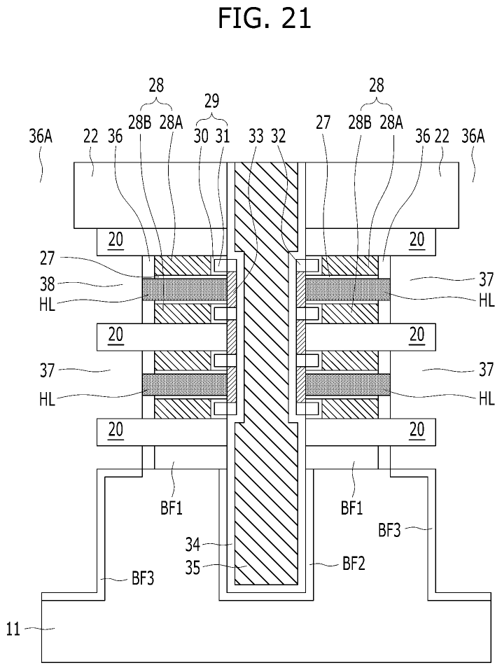

Referring to FIG. 21, a portion of the vertical level sacrificial structure 23 may be removed to form a second hole-type opening 36A and a second capping layer 36. The second hole-type opening 36A may extend vertically from the surface of the lower structure 11. The remaining vertical level sacrificial structure, that is, the second capping layer 36, may be disposed between the cell isolation layers 20. The second capping layers 36 may be disposed on a second side of the horizontal conductive line 28.

The second edge portions of the semiconductor layer patterns 14A may be exposed by the second hole-type opening 36A and the second capping layer 36.

Subsequently, the semiconductor layer patterns 14A may be horizontally recessed. As a result, the horizontal layer HL may be formed. As the second capping layer 36 and the horizontal layer HL are formed, storage openings 37 may be formed. A second end of the horizontal layer HL may be exposed by the storage opening 37. The storage openings 37 may be disposed between the cell isolation layers 20.

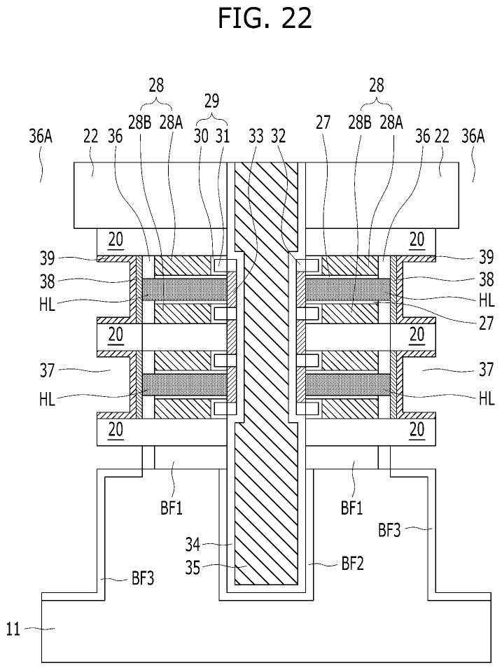

Referring to FIG. 22, a second contact node 38 may be formed on a second side of the horizontal layer HL. The second contact node 38 may include doped polysilicon. After the second contact node 38 is formed, an annealing process may be performed subsequently.

According to another embodiment of the present invention, referring to FIG. 1B, a second doped region DR may be formed in the second edge portion of the semiconductor layer patterns 14A. The forming of the second doped region DR may include depositing polysilicon that is doped with an N-type impurity, performing a heat treatment, and removing the doped polysilicon. The second doped region DR may include an impurity diffused from the doped polysilicon. According to another embodiment of the present invention, the second doped region DR may be formed by a process of doping an impurity. The second doped region DR may include an impurity to be diffused from the second contact node 38.

Subsequently, the first electrode 39 of the data storage element may be formed over the second contact node 38. The first electrode 39 may have a horizontally oriented cylindrical shape.

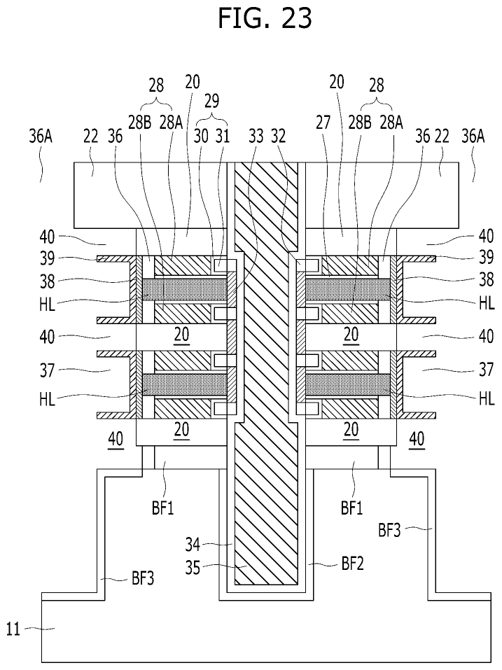

Referring to FIG. 23, the cell isolation layers 20 may be horizontally recessed (refer to a reference numeral 40). Accordingly, the outer walls of the first electrodes 39 may be exposed.

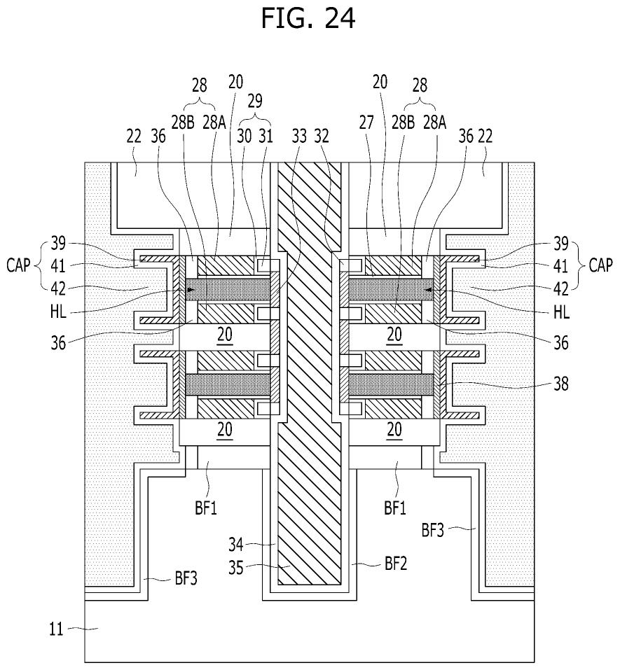

Referring to FIG. 24, a dielectric layer 41 and a second electrode 42 may be sequentially formed over the first electrodes 39. The first electrode 39, the dielectric layer 41 and the second electrode 42 may become a data storage element CAP.

The first electrode 39 may include an inner space and a plurality of outer surfaces, and the inner space of the first electrode 39 may include a plurality of inner surfaces. The outer surfaces of the first electrode 39 may include a vertical outer surface and a plurality of horizontal outer surfaces. The vertical outer surface of the first electrode 39 may contact the second contact node 38, and the horizontal outer surfaces of the first electrode 39 may contact the dielectric layer 41. The inner space of the first electrode 39 may be a three-dimensional space. The dielectric layer 41 may conformally cover the inner and outer surfaces of the first electrode 39. The second electrode 42 may be disposed in the space inside of the first electrode 39 over the dielectric layer 41.

The first electrode 39 may have a cylindrical shape. The cylindrical shape of the first electrode 39 may include cylindrical inner surfaces and cylindrical outer surfaces. The dielectric layer 41 and the second electrode 42 may be disposed on the cylindrical inner surfaces of the first electrode 39.

The first electrode 39 and the second electrode 42 may include a metal, a noble metal, a metal nitride, a conductive metal oxide, a conductive noble metal oxide, a metal carbide, a metal silicide, or a combination thereof. For example, the first electrode 39 and the second electrode 42 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode 42 may include a combination of a metal-based material and a silicon-based material. For example, the second electrode 42 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inner space of the first electrode 39, and titanium nitride (TiN) may serve as a second electrode 42 of a capacitor CAP, and tungsten nitride may be a low-resistance material.

The dielectric layer 41 may be referred to as a capacitor dielectric layer or a memory layer. The dielectric layer 41 may include silicon oxide, silicon nitride, a high-k material, a ferroelectric material, an antiferroelectric material, or a combination thereof. The dielectric layer 41 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 41 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack.

According to another embodiment of the present invention, an interface control layer for improving leakage current may be further formed between the first electrode 39 and the dielectric layer 41. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 42 and the dielectric layer 41.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a lower structure;
a plurality of horizontal layers horizontally oriented over the lower structure;
a first conductive line commonly coupled to first ends of the horizontal layers and extending in a direction perpendicular to the lower structure;
a plurality of second conductive lines crossing the horizontal layers, respectively;
a plurality of data storage elements coupled to second ends of the horizontal layers, respectively, and stacked in the direction perpendicular to the lower structure;
a plurality of capping layers disposed between the second conductive lines and the first conductive line; and
a plurality of the blocking layers disposed between the capping layers and the first conductive line.

2. The semiconductor device of claim 1, wherein the blocking layers include a dielectric material that is selectively grown from the capping layers.

3. The semiconductor device of claim 1, wherein the blocking layers include silicon carbon oxide.

4. The semiconductor device of claim 1, wherein the capping layers include silicon oxide, silicon nitride, or a combination thereof.

5. The semiconductor device of claim 1, wherein each of the capping layers includes a first liner and a second liner that is partially surrounded by the first liner, and
each of the blocking layers includes a material that is selectively deposited from a surface of the second liner.

6. The semiconductor device of claim 5, wherein the first liner includes silicon oxide, and
the second liner includes silicon nitride, and
the blocking layers include silicon carbon oxide.

7. The semiconductor device of claim 1, wherein the capping layers include silicon nitride, and the blocking layers include silicon carbon oxide.

8. The semiconductor device of claim 1, further comprising:
a first contact node surrounding an outer wall of the first conductive line;
an extension portion disposed between the first contact node and the horizontal layer; and
a second contact node disposed between the data storage element and the horizontal layer.

9. The semiconductor device of claim 8, wherein the first contact node, the second contact node, and the extension portion include polysilicon.

10. The semiconductor device of claim 8, wherein each of the horizontal layers includes:
a first doped region coupled to the extension portion;
a second doped region coupled to the second contact node; and
a channel region disposed between the first doped region and the second doped region.

11. The semiconductor device of claim 10, wherein each of the first and second contact nodes includes doped polysilicon, and
the first doped region includes an impurity diffused from the first contact node, and
the second doped region includes an impurity diffused from the second contact node.

12. The semiconductor device of claim 1, wherein the horizontal layers include monocrystalline silicon.

13. The semiconductor device of claim 1, wherein each of the second conductive lines includes
double second conductive lines vertically facing each other with the horizontal layers interposed therebetween.

14. The semiconductor device of claim 1, wherein the data storage elements include capacitors.

15. The semiconductor device of claim 1, wherein each of the data storage elements includes
a first electrode coupled to each of the horizontal layers;
a dielectric layer over the first electrode; and
a second electrode over the dielectric layer, and
the first electrode has a horizontally oriented cylindrical shape.
